(19) United States
(12) Patent Application Publication
(10) Pub. No.: US 2026/0142488 A1
(43) Pub. Date: May 21, 2026

(54) BATTERY CONTROL METHOD, A NON-TRANSITORY COMPUTER READABLE MEDIUM STORING A BATTERY CONTROL PROGRAM, AND METHOD FOR UTILIZING SECONDARY BATTERY SYSTEM

(71) Applicant: TOYOTA BATTERY CO., LTD., Kosai-shi (JP)

(72) Inventors: Yuya INAGAKI, Okazaki-shi (JP); Soichiro FUKAMACHI, Toyohashi-shi (JP); Keita MATSUMOTO, Toyohashi-shi (JP)

(21) Appl. No.: 19/391,368

(22) Filed: Nov. 17, 2025

(30) Foreign Application Priority Data
Nov. 19, 2024 (JP) 2024-201797

(51) Int. Cl. H02J 7/00; G01R 31/367; G01R 31/388; G01R 31/392; H01M 10/48

(52) U.S. Cl. CPC H02J 7/94; G01R 31/367; G01R 31/388; G01R 31/392; H01M 10/486; H02J 7/82; H02J 7/84; H02J 7/96; H02J 7/977

(57) ABSTRACT

A method according to the present disclosure includes: a state estimation processing of obtaining a charge/discharge current, a battery voltage, and a temperature to estimate state-of-charge and a state of a secondary battery; an automatic adaptation processing of updating battery parameters applied to a state estimation model used in the state estimation processing so as to be adapted to a current state of the secondary battery; and a suppression control processing of limiting an output of the secondary battery based on a result of estimation performed utilizing the state estimation model and executing a suppression control processing for prolonging the battery life of the secondary battery, the respective processing being implemented by automated computation performed by a computer, in which in the suppression control processing, execution of suppression control is refrained until the battery parameters show a degree of adaptation equal to or greater than a preset threshold.

### INCORPORATION BY REFERENCE

This application is based upon and claims the benefit of priority from Japanese patent application No. 2024-201797, filed on Nov. 19, 2024, the disclosure of which is incorporated herein in its entirety by reference for all purposes.

### BACKGROUND

The present disclosure relates, for example, to a battery control method, a non-transitory computer readable medium storing a battery control program, and a method for utilizing a secondary battery system in which a secondary battery whose manufacturing process and usage history are unknown is utilized.

In recent years, secondary batteries that have been used for certain purposes are being recycled to be used for other purposes. However, in the case of utilizing a secondary battery, if the battery parameters for grasping the state of the secondary battery cannot be grasped, the battery control becomes unstable due to overcharging, overdischarging, etc., of the secondary battery. Therefore, a technique for grasping the state of state-of-health of a secondary battery is disclosed in Japanese Unexamined Patent Application Publication No. 2009-080093.

The method for detecting internal information of a secondary battery described in Japanese Unexamined Patent Application Publication No. 2009-080093, is a method for detecting internal information of a secondary battery, wherein a first step of acquiring a charge/discharge curve unique to a positive electrode material and a charge/discharge curve unique to a negative electrode material as basic data and acquiring a charge/discharge curve of a battery to be detected as an actual measured value; a second step of obtaining the charge/discharge curve of the positive electrode inside the battery to be detected and the charge/discharge curve of the negative electrode inside the battery to be detected by using the charge/discharge curve unique to the positive electrode material, the charge/discharge curve unique to the negative electrode material, and the charge/discharge curve of the battery to be detected as an actual measured value, and pre-set correction parameters; and a third step of outputting at least one of the charge/discharge curve of the positive electrode and the charge/discharge curve of the negative electrode inside determined in the second step, and the correction parameters used in the determination.

### SUMMARY

However, with the technique described in Japanese Unexamined Patent Application Publication No. 2009-080093, there is a problem that it can be used only after the variation in performance of the new battery and the performance including the used battery are obtained by testing, and the actual battery performance is limited in consideration of the variation in the performance.

The present disclosure has been made in view of the above-mentioned circumstances, and it is an object of the present disclosure to promote the reuse of an unidentified secondary battery whose performance has been being fully elicited.

According to an aspect of the present disclosure, a battery control method includes:
a state estimation processing of obtaining a charge/discharge current, a battery voltage, and a temperature of a secondary battery to estimate state-of-charge and a state of the secondary battery;
an automatic adaptation processing of updating battery parameters applied to a state estimation model used in the state estimation processing so as to be adapted to a current state of the secondary battery; and
a suppression control processing of limiting an output of the secondary battery based on a result of estimation performed utilizing the state estimation model and executing a suppression control processing for prolonging the battery life of the secondary battery, the respective processing being implemented by automated computation performed by a computer,
in which in the suppression control processing, execution of suppression control is refrained until the battery parameters show a degree of adaptation equal to or greater than a preset threshold.

According to another aspect of the present disclosure, a non-transitory computer readable medium includes stores a battery control program for causing a computer to perform:
a state estimation processing of obtaining a charge/discharge current, a battery voltage, and a temperature of a secondary battery to estimate state-of-charge and a state of the secondary battery;
an automatic adaptation processing of updating battery parameters applied to a state estimation model used in the state estimation processing so as to be adapted to a current state of the secondary battery; and
a suppression control processing of limiting an output of the secondary battery based on a result of estimation performed utilizing the state estimation model and executing a suppression control for prolonging the battery life of the secondary battery,
in which in the suppression control processing, execution of suppression control is refrained until the battery parameters show a degree of adaptation equal to or greater than a preset threshold value.

According to another aspect of the present disclosure, a method for utilizing a secondary battery system includes:
setting a first performance level, a second performance level, and a third performance level at which the secondary battery is to be operated; and
designating at least one of the performance levels at which the secondary battery is to be operated and operating the secondary battery at the designated performance level, the performance levels including:
a first performance level at which charge-discharge operation is performed by applying a standard parameter preset based on a battery type of a secondary battery and by applying an upper and lower limit voltages preset based on the battery type of the secondary battery;
a second performance level at which charge-discharge operation is performed by applying the setting of the upper and lower limit voltages according to the state-of-health of the secondary battery calculated based on the state estimation model and the limitation on the input-output power in accordance with the state-of-charge of the secondary battery while performing state-of-charge estimation processing in which the battery parameters calculated based on the state-of-health of the secondary battery are applied to the state estimation model; and
a third performance level at which charge-discharge operation is performed according to the state of the secondary battery by applying the power limit value calculated in a state estimation processing of the secondary battery and the automatic adaptation processing of updating the battery parameters to adapt to the current state of the secondary battery,
in which in operating the secondary battery at the third performance level, a computer is caused to perform:
the state estimation processing of obtaining a charge/discharge current, a battery voltage, and a temperature of the secondary battery to estimate a state-of-charge and a state of the secondary battery;
the automatic adaptation processing of updating the battery parameters applied to a state estimation model used in the state estimation processing so as to be adapted to a current state of the secondary battery; and
the suppression control processing of limiting an output of the secondary battery based on a result of estimation performed utilizing the state estimation model and executing a suppression control for prolonging the battery life of the secondary battery,
in which in the suppression control processing, execution of suppression control is refrained until the battery parameters show a degree of adaptation equal to or greater than a preset threshold value.

According to a battery control method, a non-transitory computer readable medium storing a battery control program, and a method for utilizing a secondary battery system of the present disclosure, it is possible to promote the reuse of an unidentified secondary battery whose performance has been fully elicited.

The above and other objects, features and advantages of the present disclosure will become more fully understood from the detailed description given hereinbelow and the accompanying drawings.

### BRIEF DESCRIPTION OF DRAWINGS

FIG. 1 is a flowchart for explaining a method for utilizing a secondary battery system according to a first embodiment;

FIG. 2 is a flowchart for explaining the flow of operating the secondary battery system according to the first embodiment at a first performance level;

FIG. 3 is a flowchart for explaining the flow of operating the secondary battery system according to the first embodiment at a second performance level;

FIG. 4 is a flowchart for explaining the flow of initial state-of-health estimation processing according to the first embodiment;

FIG. 5 is a flowchart for explaining the flow of battery parameter estimation processing according to the first embodiment; and

FIG. 6 is a flowchart for explaining the flow of operating the secondary battery system according to the first embodiment at a second performance level.

### DESCRIPTION OF EMBODIMENTS

For clarity of explanation, the following descriptions and drawings are omitted and simplified as appropriate. In addition, each element described in the drawings as a functional block for performing various processing may be configured of a CPU (Central Processing Unit), a memory, or other circuits in terms of hardware, and may be implemented by a program loaded into the memory in terms of software. Therefore, it will be understood by those skilled in the art that these functional blocks can be implemented in various forms by hardware only, software only, or a combination thereof, and is not limited to any of them. In each of the drawings, the same reference numerals are assigned to the same elements, and duplicate descriptions are omitted as necessary.

Moreover, the above-described program includes a group of instructions (or software code) for causing the computer to perform one or more functions described in the embodiment when read into the computer. The program may be stored in a non-transitory computer readable medium or a tangible storage medium. By way of example, and not a limitation, non-transitory computer readable media or tangible storage media includes a random-access memory (RAM), a read-only memory (ROM), a flash memory, a solid-state drive (SSD) or other types of memory technologies, a CD-ROM, a digital versatile disc (DVD), a Blu-ray (registered trademark) disc, or other types of optical disc storage, and magnetic cassettes, magnetic tape, magnetic disk storage, or other types of magnetic storage devices. The program may be transmitted on a transitory computer readable medium or a communication medium. By way of example, and not a limitation, transitory computer readable media or communication media can include electrical, optical, acoustical, or other forms of propagated signals.

It should be noted that the method for utilizing a secondary battery system according to the first embodiment described below is performed by automatic processing in cooperation of at least one program executed on a computer such as an ECU (Electric Control Unit) for controlling the charging and discharging of the secondary battery.

### First Embodiment

A description is given below on a method for utilizing a secondary battery system in which a secondary battery is reused. In addition, in the method for utilizing a battery according to the first embodiment, the battery parameters and performance are evaluated based on a battery cell alone regardless of whether the secondary battery is used as a battery pack consisting of a plurality of batteries. Therefore, the term battery cell is used in the description. In the method for utilizing a secondary battery system according to the first embodiment, the battery type of the secondary battery is not limited, but for the sake of description, a lithium ion secondary battery is used as the secondary battery.

In the method of utilizing the secondary battery system according to the first embodiment, it is possible to recycle even an unidentified secondary battery whose information on its design and manufacture is hard to obtain. In addition, in the method of utilizing the secondary battery system according to the first embodiment, it is possible to shorten the unutilized period of the battery cell because the accuracy of information for grasping the current characteristics of the battery cell is improved while utilizing the battery cell in a specific application. The method of utilizing the secondary battery system according to the first embodiment will be specifically described below.

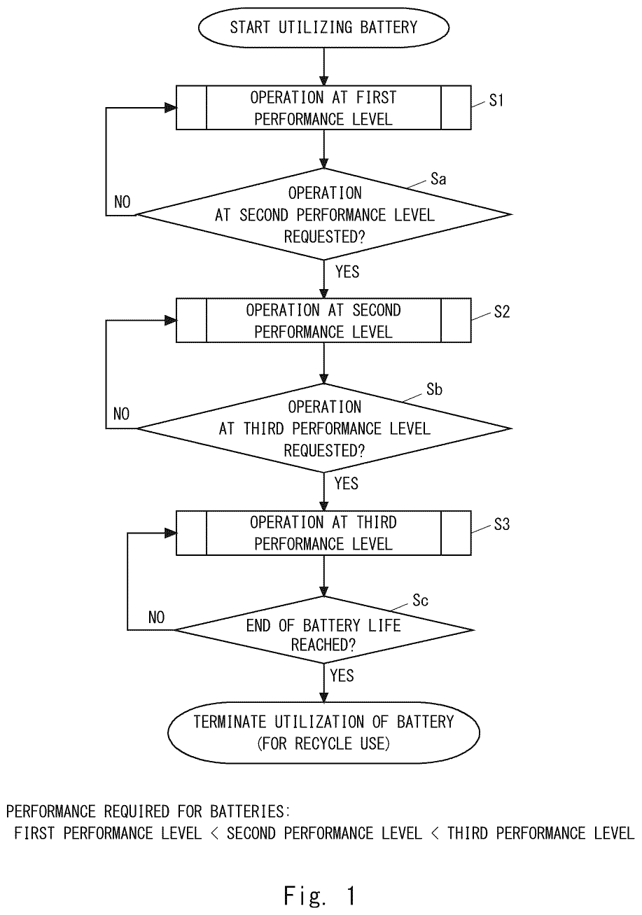

FIG. 1 is a flowchart for explaining the method for utilizing a secondary battery system according to the first embodiment. As shown in FIG. 1, in the secondary battery system according to the first embodiment, a performance level at which the secondary battery is to be operated is designated from three performance levels and then the secondary battery is operated at the designated performance level. For example, in the case where the first performance level is designated as the performance level at which the secondary battery it to be operated (Step S1), the secondary battery is continued to be operated at the first performance level in Step S1. In the case where the second performance level is designated as the performance level at which the secondary battery it to be operated (Step S2), the secondary battery is operated at the first performance level once in Step S1, and then the performance level at which the battery system is to be operated is shifted to the second performance level in Step S2. In the case where the third performance level is designated as the performance level at which the secondary battery is to be operated (Step S3), the secondary battery is operated at the first performance level in Step S1 once and then at the second performance level in Step S2 once, and then the performance level at which the battery system is to be operated is shifted to the third performance level in Step S3. In FIG. 1, Steps Sa and Sb are shown as decision-making processing for making decision on the performance level at which the battery system is to be operated. In addition, in performing operation at the third performance level, Step Sc, in which a decision is made on whether the battery life of the secondary battery has been reached or not, is shown, since utilization of the secondary battery is terminated based on whether the battery life of the secondary battery has been reached or not.

Here, operation at each of the first performance level, the second performance level, and the third performance level will be described. In performing operation at the first performance level, charge-discharge operation is performed by applying the standard parameters preset based on the battery type of the secondary battery, and by applying the upper and lower limit voltages preset based on the type of the secondary battery. In performing operation at the first performance level, for example, in the case of a ternary secondary battery, the lower limit voltage is set to 3V, the upper limit voltage is set to 4.2V, and battery control is performed such that state of charge is estimated based on the battery voltage.

In performing operation at the second performance level operation, charge-discharge operation is performed by applying the setting of the upper and lower limit voltages according to the state-of-health of the secondary battery calculated based on the state estimation model and the limitation on the input-output power in accordance with the state-of-charge of the secondary battery while performing state-of-charge estimation processing in which the battery parameters calculated based on the state-of-health of the secondary battery are applied to the state estimation model. For example, in performing operation at the second performance level, battery control is performed such that the state of charge estimated by current integration is corrected by estimating the open circuit voltage (OCV) which is the release voltage from the measured voltage. In performing operation at the second performance level, the parameters to be used for controlling the secondary battery are extracted with higher accuracy, and it is suitable for applications where estimation levels are required in estimating the upper and lower limit voltages and the state of charge.

In performing operation at the third performance level, state charge-discharge operation in accordance with the state of the secondary battery is performed by applying the power limit value calculated in the state estimation processing of the secondary battery and automatic adaptation processing of updating the battery parameters to adapt to the current state of the secondary battery. For example, in performing operation at the third performance level, the life of the battery, lithium precipitation suppression, power limit, and the like are calculated from the obtained battery parameters, and to perform more precise control. In performing operation at the third performance level, since the life of the secondary battery and the power limit for maximizing the performance of the secondary battery can be calculated, the information on the charging-discharging can be reflected in the battery model.

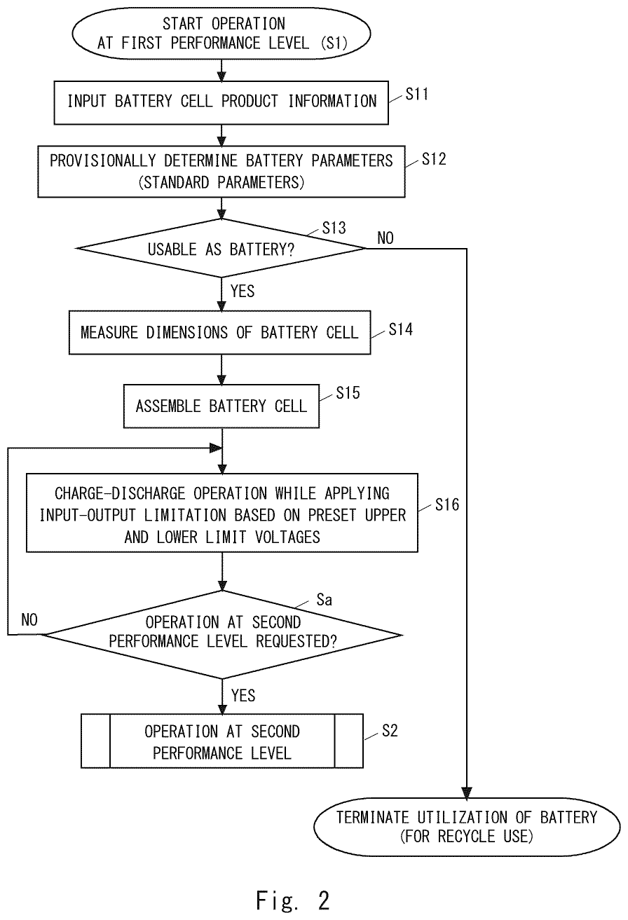

The operations at the first performance level to the third performance level will be described in detail below. First, FIG. 2 shows a flowchart for explaining the flow of performing operation at the first performance level of the secondary battery system according to the first embodiment. As shown in FIG. 2, in performing operation at the first performance level, first, the product information of a battery cell is input regardless of whether the battery cell is an identified battery cell or not (Step S11). Specifically, in the method of utilizing the secondary battery system according to the first embodiment, information including at least the battery type of the battery cell to be put into use is input to the computer as the product information in Step S11. There are different types of the secondary battery such as a lead-acid battery, a nickel-hydrogen battery, and a lithium-ion battery, depending on the material used in manufacture of the secondary battery. Therefore, in the method of utilizing the secondary battery system according to the first embodiment, information about the material for the battery cell to be used, such as a lead storage battery, a nickel hydrogen storage battery, and a lithium ion storage battery, is given to the computer as a battery type.

Next, in Step S12, the standard parameters preset for each battery type of the battery cell to be used are provisionally determined as battery parameters. Here, the standard parameters in the method of utilizing the secondary battery according to the first embodiment are information disclosed to the public, for example, a value determined in advance by an entity that reuses the battery cell based on information disclosed on a website or the like by a material manufacturer who supplies the material of the battery cell. For example, the standard parameters include the thickness of the electrode foil, the thickness of the separator, the density of the active material layer coated on the electrode foil, the specific capacity of the active material layer, and the electrode capacity of the active material layer.

Next, a decision is made in Step S13 as to whether the secondary battery can be utilized or not. Specifically, in Step S13, it is confirmed whether the voltage range of the secondary battery is within the normal range or not, for example, and whether there is any visible defect such as liquid leakage, and in the case where it is confirmed that the secondary battery is normal (usable), the next step of Step S14 is performed. On the other hand, in the case where a defect is confirmed in the secondary battery in Step S13, the utilization of the secondary battery is terminated.

After Step S13, Step S14 for measuring the dimensions of the available secondary battery, and Step S15 for assembling the target secondary battery into a chargeable/dischargeable state are performed. Thereafter, in performing operation at the first performance level, the pre-set upper and lower limit voltages are set based on the battery parameters provisionally set in Step S12 based on the type of battery, and the charge/discharge operation is performed while limiting the input/output power based on the upper and lower limit voltages (Step S16). Then, in the secondary battery system according to the first embodiment, in the case where the first performance level is designated as the performance level at which the secondary battery it to be operated, (NO branch in Step Sa), the charge/discharge operation of Step S16 is continued. On the other hand, in the secondary battery system according to the first embodiment, in the case where the second performance level is designated as the performance level at which the secondary battery it to be operated, (YES branch in Step Sa), the performance level at which the secondary battery is to be controlled is shifted to the second performance level (Step S2).

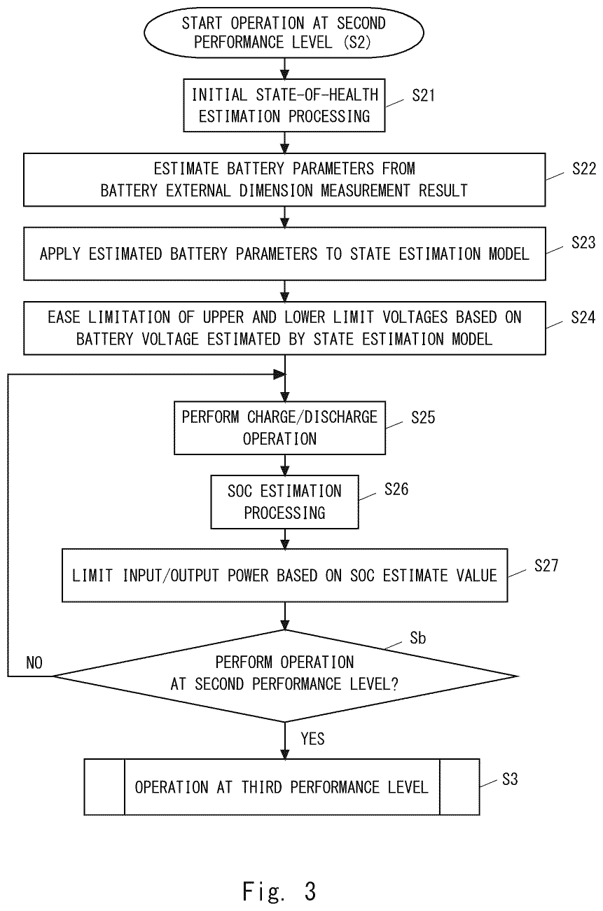

FIG. 3 shows a flowchart for explaining the flow of performing operation at the second performance level of the secondary battery system according to the first embodiment. As shown in FIG. 3, in performing operation at the second performance level, the initial state-of-health estimation processing (Step S21) is first performed. In the initial state-of-health estimation, the amount of change in the battery resistance of the battery cell is calculated from the current and the voltage values that can be obtained in repeatedly charging and discharging the battery cell assembled in Step S15, and parameters as an index of the characteristic state-of-health of the battery cell is estimated based on the amount of change in the battery resistance of the battery cell. By performing this initial state-of-health estimation processing, the control of the battery cell can be optimized according to the state of health of the battery, and the battery cell can be used safely and with higher performance. The details of the initial state-of-health estimation processing will be described later.

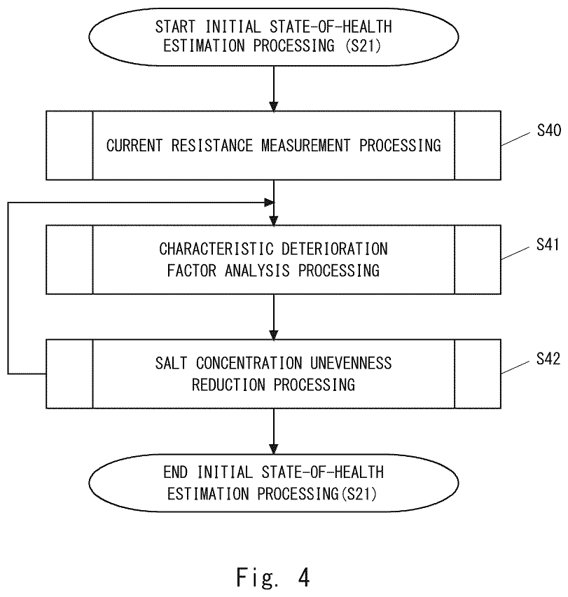

FIG. 4 is a flowchart for explaining the flow of the initial state-of-health estimation processing according to the first embodiment. As shown in FIG. 4, in the initial state-of-health estimation processing according to the first embodiment, the current resistance measurement processing (Step S40), the characteristic deterioration factor analysis processing (Step S41), and salt concentration unevenness reduction processing (Step S42) are performed. In the current resistance measurement processing, charge/discharge is performed on the battery cell, and the current battery resistance of the battery cell is measured based on the charge/discharge current and the output voltage of the battery cell. In the characteristic deterioration factor analysis processing, a current value is estimated for each deterioration factor parameter which is a characteristic deterioration factor of the battery cell based on the difference between the battery resistance of the battery cell in a new state which has been previously estimated and the current battery resistance measured in the current resistance value measurement processing. In the salt concentration unevenness reduction processing, the current battery resistance measured after a fixed period of charge/discharge processing in which the charge/discharge current is limited to a preset charge/discharge rate changes from a decrease to an increase, and the amount of change between the current battery resistance at the previous measurement and the current battery resistance at the current measurement is within a pre-set range, the deterioration factor parameter at that time is set as a determined value. Then, in the initial state-of-health estimation processing, in the case where the current battery resistance measured in the salt concentration unevenness reduction processing is lower than the current battery resistance at the previous measurement, the characteristic deterioration factor analysis processing is executed based on the newly measured current battery resistance.

Subsequently, in the method for utilizing the secondary battery system according to the first embodiment, the battery parameter estimation processing is performed to estimate the battery parameters from the external dimension measurement result of the secondary battery (measurement result in Step S14) (Step S22). In the battery parameter estimation processing, after measuring the dimensions of a battery cell judged to be a target battery type, the battery cell is assembled to be in a charge-dischargeable state, and the state of health of the battery cell and the current electrode capacity as the current electrode capacity of the battery cell are estimated based on the charge-discharge current value obtained by charging and discharging the assembled battery cell and the output voltage value of the battery cell, and the thickness of the active material layer of the battery cell is estimated based on the measurement results of the dimensions of the battery cell.

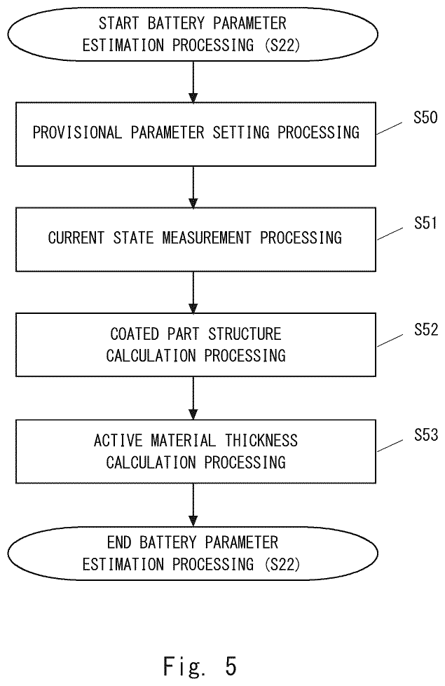

Here, the battery parameter estimation processing will be described more specifically. The battery parameter estimation processing uses the provisional value obtained in Step S12 and the measured value obtained in Step S14 to estimate the characteristics of the battery cell in the new state (for example, capacity, etc.) and the design parameters indicating the structure of the battery cell. In other words, the battery characteristic estimation processing obtains the characteristics of the battery cell in the new state (for example, capacity, etc.) and the design parameters indicating the structure of the battery cell without destroying the battery cell. FIG. 5 shows a flowchart for explaining the flow of the battery parameter estimation processing according to the first embodiment. As shown in FIG. 5, the battery parameter estimation processing performs the provisional parameter setting processing (Step S50), the current state measurement processing (Step S51), the coated part structure calculation processing (Step S52), and the active material thickness calculation processing (Step S53).

In the provisional parameter setting processing, for example, the standard parameters input in Step S12 for the aluminum foil thickness, the copper foil thickness, the separator thickness, the positive electrode density, the positive electrode specific capacity, the negative electrode density, the negative electrode specific capacity, the initial positive electrode capacity, and the initial negative electrode capacity are set as the provisional values for each parameter.

In the current state measurement processing, the battery cell is charged and discharged while controlling the battery cell by using the provisional values set in the provisional parameter setting processing, and the state of health of the battery cell and the current positive electrode capacity and the current negative electrode capacity which are the current electrode capacities of the battery cell are estimated.

In the coated part structure calculation processing, the cross-sectional area of the electrode body housed in the battery cell viewed from the side orthogonal to the electrode stacking direction and the width of the coated part of the electrode body are calculated based on the dimensions (for example, in the battery cell obtained in Step S14, the width, the height, and the thickness of the case containing the electrode body) that can be measured without destroying the battery cell.

In the active material thickness calculation processing, the thickness of the positive electrode active material layer and the thickness of the negative electrode active material layer are calculated by using the aluminum foil thickness, the copper foil thickness, the separator thickness, the positive electrode density, the positive electrode specific capacity, the negative electrode density, and the negative electrode specific capacity whose provisional values are set in the provisional parameter setting processing in Step S50, the current positive electrode capacity and the current negative electrode capacity whose estimate values are calculated in the current state measurement processing in Step S51, the cross-sectional area of the electrode body calculated in the coated part structure calculation processing in Step S52, and width of the coated part of the electrode body.

Subsequently, in the battery system according to the first embodiment, the battery parameters calculated in the battery parameter estimation processing in Step S22 are applied to the state estimation model (Step S23), and limitation of the upper and lower limit voltages are eased compared to the limitation of the upper and lower limit voltages set in Step S16 based on the battery voltage estimated by the state estimation model (Step S24). Then, in the secondary battery system according to the first embodiment, while performing the charge/discharge operation (Step S25), SOC estimation processing is performed (Step S26), and the input/output power is limited based on the state-of-charge estimate value (Step S27). Then, in the secondary battery system according to the first embodiment, in the case where the second performance level is designated as the performance level at which the secondary battery is to be operated (NO branch in Step Sb), the charge/discharge operation in Steps S25 to S27 are continued. On the other hand, in the secondary battery system according to the first embodiment, in the case where the third performance level is designated as the performance level at which the secondary battery is to be operated (YES branch in Step Sb), the performance level at which the battery system is to be operated is shifted to the third performance level (Step S3).

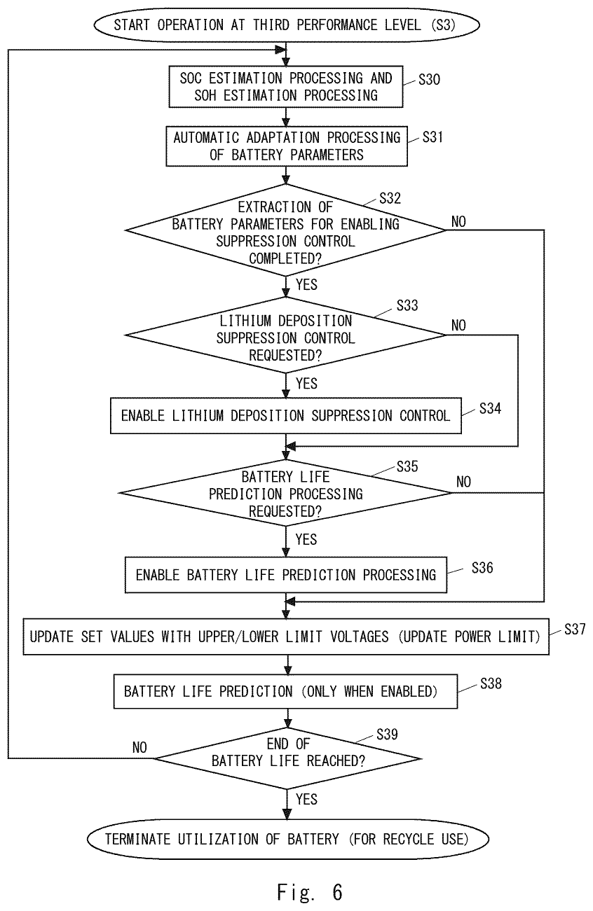

FIG. 6 is a flowchart for explaining the flow of performing operation at the third performance level of the secondary battery system according to the first embodiment. As shown in FIG. 6, in performing operation at the third performance level, the charge-discharge current, the battery voltage, and the battery temperature of the secondary battery are measured, and the measured charge-discharge current, battery voltage, and battery temperature are input to the state estimation model to perform the SOC (State Of Charge) estimation processing and SOH (State Of Health) estimation processing (Step S30). Subsequently, the secondary battery system according to the first embodiment performs the automatic adaption processing of the battery parameters to update the battery parameters so as to reduce the difference between the estimate battery voltage calculated by the state-of-charge estimation processing and the actually measured battery voltage (Step S31). Here, the magnitude of the difference between the estimate battery voltage and the actually measured battery voltage can be considered as the state estimation model or one of the indicators of the degree of adaptation of the battery parameters. For example, it can be considered that the smaller the difference between the estimate battery voltage and the actually measured battery voltage, the higher the degree of adaptation.

Subsequently, the secondary battery system according to the first embodiment makes a judgement as to whether extraction of the battery parameters for enabling the suppression control has been completed (Step S32). For example, in Step S32, in the case where the adaptation of the battery parameters is equal to or greater than a preset threshold, it can be judged that the extraction of the battery parameters for enabling the suppression control has been completed, and in the case where the degree of adaptation of the battery parameters is lower than a preset threshold, it can be judged that the extraction of the battery parameters for enabling the suppression control has not been completed. In the example shown in FIG. 6, two types of suppression control are lithium precipitation suppression control and battery life prediction processing, but the suppression control is not limited to these two as long as the suppression control suppresses the input/output power of the secondary battery below the maximum power of the secondary battery.

In the case where it is judged that the extraction of the battery parameters has not been completed in Step S32, the power limit update processing is performed based on the result of state of charge estimation processing in Step S30 to update the set values of the upper/lower limit voltages corresponding to the current state of the secondary battery (Step S37). On the other hand, in the case where the battery parameters have been extracted in Step S32, in the secondary battery system according to the first embodiment, judgement is made as to whether there is a request for lithium deposition suppression control from the user (Step S33). In the case where there is a request for lithium deposition suppression control (YES branch in Step S33), the lithium deposition suppression control is enabled, and the lithium deposition suppression control is performed in the subsequent processing (Step S34). On the other hand, in the case where there is no request for lithium deposition suppression control (NO branch in Step S33), the lithium deposition suppression control is kept disabled.

Judgement is also made as to whether there is a request for battery life prediction processing from the user (Step S35). In the case where there is a request for battery life prediction processing (YES branch in Step S35), the battery life prediction processing is enabled, and the battery life prediction processing is performed in the subsequent processing (Step S36). On the other hand, in the case where there is no request for battery life prediction processing (NO branch in Step S35), the battery life prediction processing is kept disabled.

After the processing of Steps S33 to S36, the processing of Step S37 is performed. In the case where the battery life prediction processing is enabled in Step S36, the battery life prediction processing is performed after the power limit update in Step S37 (Step S38). Then, the respective processing of Steps S30 to S39 are repeated until the battery life of the secondary battery ends (YES branch in Step S39). After the battery life of the secondary battery ends, the utilization of the battery is terminated.

As described above, according to the method of utilizing the secondary battery system according to the first embodiment, it is possible to immediately determine the output limit suitable for application in which the secondary battery is utilized and apply the control of the processing load suitable for the application. Moreover, according to the method of utilization of the secondary battery system according to the first embodiment, it is possible to increase the state estimate accuracy of the battery while utilizing the secondary battery.

Further, in the control of the secondary battery, the suppression control is carried out for the purpose of prolonging the battery life or performing stability control of the battery. However, during the period in which the degree of adaptation of the state estimation model or that of the battery parameters is low, the suppression control may work strongly against the power of the secondary battery. However, in the secondary battery system according to the first embodiment, since the suppression control is disabled until the degree of adaptation increases, the output performance of the secondary battery is not reduced by the suppression control stronger than intended. In other words, in the secondary battery system according to the first embodiment, it is possible to maximize the battery performance of a battery while using the battery.

From the disclosure thus described, it will be apparent that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A battery control method comprising:
a state estimation processing of obtaining a charge/discharge current, a battery voltage, and a temperature of a secondary battery to estimate state-of-charge and a state of the secondary battery;
an automatic adaptation processing of updating battery parameters applied to a state estimation model used in the state estimation processing so as to be adapted to a current state of the secondary battery; and
a suppression control processing of limiting an output of the secondary battery based on a result of estimation performed utilizing the state estimation model and executing a suppression control for prolonging a battery life of the secondary battery, the suppression control processing being implemented by automated computation performed by a computer,
wherein in the suppression control processing, execution of the suppression control is refrained until the battery parameters show a degree of adaptation equal to or greater than a preset threshold.

2. The battery control method according to claim 1, wherein the suppression control is maintained in a disabled state, in which the suppression control is not executed, in the case where there is no instruction from the outside to enable the suppression control.

3. The battery control method according to claim 1, wherein the suppression control processing includes at least one of:
lithium deposition suppression control of suppressing the charge/discharge current to the secondary battery so as to suppress a lithium deposition amount of the secondary battery, the lithium deposition amount being estimated utilizing the state estimation model; and
a battery life estimation processing of the secondary battery which is estimated utilizing the state estimation model.

4. A non-transitory computer readable medium storing a battery control program for causing a computer to perform:
a state estimation processing of obtaining a charge/discharge current, a battery voltage, and a temperature of a secondary battery to estimate state-of-charge and a state of the secondary battery;
an automatic adaptation processing of updating battery parameters applied to a state estimation model used in the state estimation processing so as to be adapted to a current state of the secondary battery; and
a suppression control processing of limiting an output of the secondary battery based on a result of estimation performed utilizing the state estimation model and executing a suppression control for prolonging a battery life of the secondary battery,
wherein in the suppression control processing, execution of suppression control is refrained until the battery parameters show a degree of adaptation equal to or greater than a preset threshold value.

5. A method for utilizing a secondary battery system, comprising:
setting performance levels at which a secondary battery is to be operated; and
designating at least one of the performance levels at which the secondary battery is to be operated and operating the secondary battery at the designated performance level, the performance levels including:
a first performance level at which charge-discharge operation is performed by applying a standard parameter preset based on a battery type of a secondary battery and by applying an upper and lower limit voltages preset based on the battery type of the secondary battery;
a second performance level at which charge-discharge operation is performed by applying the setting of the upper and lower limit voltages according to a state-of-health of the secondary battery calculated based on a state estimation model and a limitation on input-output power in accordance with a state-of-charge of the secondary battery while performing state-of-charge estimation processing in which battery parameters calculated based on the state-of-health of the secondary battery are applied to the state estimation model; and
a third performance level at which charge-discharge operation is performed according to a state of the secondary battery by applying a power limit value calculated in a state estimation processing of the secondary battery and an automatic adaptation processing of updating the battery parameters to adapt to a current state of the secondary battery,
wherein in operating the secondary battery at the third performance level, a computer is caused to perform:
the state estimation processing of obtaining a charge/discharge current, a battery voltage, and a temperature of the secondary battery to estimate the state-of-charge and the state of the secondary battery;
the automatic adaptation processing of updating the battery parameters applied to the state estimation model used in the state estimation processing so as to be adapted to the current state of the secondary battery; and
suppression control processing of limiting an output of the secondary battery based on a result of estimation performed utilizing the state estimation model and executing a suppression control for prolonging a battery life of the secondary battery,
wherein in the suppression control processing, execution of the suppression control is refrained until the battery parameters show a degree of adaptation equal to or greater than a preset threshold value.
